(19) United States
(12) Patent Application Publication
(10) Pub. No.: US 2025/0178886 A1
(43) Pub. Date: Jun. 5, 2025

(54) SEALED MICROELECTROMECHANICAL MEMBRANE DEVICE

(71) Applicant: STMicroelectronics International N.V., Geneva (CH)

(72) Inventors: Mark Andrew SHAW, Milano (IT); Lorenzo BALDO, Bareggio (IT); Filippo DANIELE, Milano (IT); Silvia ADORNO, Novate Milanese (IT)

(73) Assignee: STMicroelectronics International N.V., Geneva (CH)

(21) Appl. No.: 18/952,485

(22) Filed: Nov. 19, 2024

(30) Foreign Application Priority Data
Dec. 4, 2023 (IT) 102023000025878

(51) Int. Cl. B81B 3/00; B81C 1/00; G01L 9/00

(52) U.S. Cl. CPC B81B 3/0072; B81C 1/00666; G01L 9/0045; G01L 9/0048; B81B 2201/0264; B81B 2203/0127; B81C 2203/019

(57) ABSTRACT

A microelectromechanical membrane sensor includes: a supporting body, containing semiconductor material and having a recess in a face; a platform, housed in the recess at a distance from the supporting body; a flexure, connecting the platform to the supporting body and configured to keep the platform suspended in the recess. A gap extends between the supporting body, the platform and the flexure. A membrane is housed in the platform and delimits a buried cavity incorporated in the platform. A sealing strip extends on the supporting body, on the platform and on the flexure along the gap.

### BACKGROUND

### Technical Field

The present disclosure relates to a sealed microelectromechanical (MEMS) membrane device and a method for manufacturing a sealed microelectromechanical membrane device.

### Description of the Related Art

As is known, an issue common to microelectromechanical membrane sensors, in particular to pressure sensors, relates to the effects of mounting operations. Generally, microelectromechanical membrane sensors and related control devices are manufactured into respective distinct semiconductor chips (a sensor chip and a control chip or ASIC-Application Specific Integrated Circuit-chip), which are bonded to a base and incorporated in a packaging structure. Subsequently, the base is soldered to a Printed Circuit Board or PCB for electrical and mechanical coupling to a user system.

In the absence of suitable measures, soldering causes significant thermal stress which, due to the different coefficients of thermal expansion, may deform the sensor chip and induce mechanical stresses on the membrane, leading to a drift in the sensing with respect to the calibration values.

To reduce the negative effects of thermal stress due to soldering, ceramic substrates are sometimes used as bases for assembling the sensor chip and the control chip. In fact, ceramic has the advantage of high stiffness and therefore deforms little with respect to polymeric substrates. On the other hand, ceramic substrates are expensive and do not allow the use of some advantageous and very common assembling techniques, such as flip chip or WLCSP (Wafer Level Chip Scale Package) techniques. The design freedom of membrane pressure sensors is thus limited.

According to a different solution, the membrane that operates as a transducer is formed in a suspended platform obtained from the sensor chip and connected thereto by flexures. The main portion of the sensor chip functions as a supporting body for the platform. The flexures may almost completely absorb the deformations of the sensor chip, as well as any shocks and vibrations, and preserve the membrane from stresses. However, if the solution is very effective in reducing the drift caused by thermomechanical stresses, it may be difficult to obtain other advantageous characteristics in many circumstances. In fact, in microelectromechanical pressure sensors, the membrane is in fluidic communication with the outside to be able to receive the pressure signals to be transduced, but, at the same time, it is often useful for the same membrane to be protected from potentially harmful agents, such as dust and humidity. Therefore, the sensitive portion of the microelectromechanical membrane device may be embedded in a potting gel, which has the property of conveying pressure variations from the outside and acts as a barrier for impurities. In sensors with suspended platform, however, waterproofing through gel deposition may be difficult to obtain. Since the interstices between the platform, the flexures and the supporting body have micrometric dimensions, the gel viscosity may make filling problematic and cause, for example, the formation of bubbles, which may affect the propagation and transduction of the pressure signals or make waterproofing ineffective. The structure with platform elastically coupled to the supporting body is therefore poorly compatible with waterproofing.

### BRIEF SUMMARY

The present disclosure provides a sealed microelectromechanical device and a method for manufacturing a sealed microelectromechanical device which allow the limitations described to be overcome or at least mitigated.

A microelectromechanical device and a method for manufacturing a microelectromechanical device is provided. The microelectromechanical membrane sensor comprising a supporting body, containing semiconductor material and having a recess in a face; a platform, housed in the recess at a distance from the supporting body; a flexure, connecting the platform to the supporting body and configured to keep the platform suspended in the recess, wherein a gap extends between the supporting body, the platform and the flexure; a membrane housed in the platform and delimiting a buried cavity incorporated in the platform; and a sealing strip extending on the supporting body, on the platform and on the flexure along the gap.

### BRIEF DESCRIPTION OF THE SEVERAL VIEWS OF THE DRAWINGS

For a better understanding of the present disclosure, preferred embodiments are provided, by way of non-limiting example, with reference to the drawings, wherein:

FIG. 1 is a top-plan view of a microelectromechanical membrane sensor in accordance with an embodiment of the present disclosure;

FIG. 2 is a cross-section through the sensor of FIG. 1, taken along line II-II of FIG. 1;

FIG. 3 is a cross-section through a microelectromechanical pressure sensor in accordance with a different embodiment of the present disclosure;

FIGS. 4-13 are cross-sections through a semiconductor wafer in subsequent processing steps of a process for manufacturing a microelectromechanical pressure sensor in accordance with an embodiment of the present disclosure; and

FIGS. 14-15 are cross-sections through a semiconductor wafer in subsequent processing steps of a process for manufacturing a microelectromechanical pressure sensor in accordance with a different embodiment of the present disclosure.

### DETAILED DESCRIPTION

The following description refers to the arrangement shown in the drawings; consequently, expressions such as “above”, “below”, “upper”, “lower”, “at the top”, “at the bottom”, “right”, “left” and the like relate to the Figures and are not to be interpreted in a limiting manner.

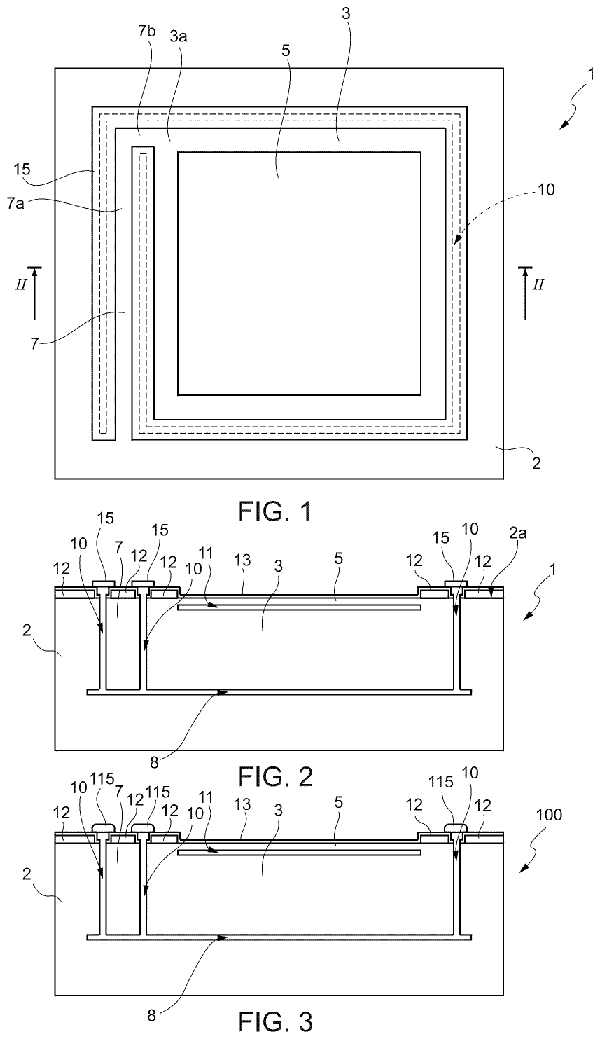

With reference to FIG. 1, a microelectromechanical membrane sensor, in particular a pressure sensor, is indicated as a whole with the number 1 and comprises a supporting body 2 and a platform 3, which houses a membrane 5 and is connected to the supporting body 2 by a flexure or bent extension 7.

The supporting body 2 is a die of semiconductor material, for example monocrystalline and/or polycrystalline silicon.

The platform 3 is housed in a recess 8 obtained in a major face 2a of the supporting body 2 and is kept suspended on a surface 2a of the same supporting body 2 by the flexure 7. More in detail, the platform 3 has generally a quadrangular, for example rectangular, shape and is spaced from the surface 2a.

In one embodiment, the flexure 7 is L-shaped and connects a vertex 3a of the platform 3 to the supporting body 2. A first branch or portion 7a of the flexure 7 is anchored to the supporting body 2 and extends substantially parallel or coplanar to one side of the platform 3. A second branch 7b of the flexure 7, that is shorter, is consecutive and substantially perpendicular or transverse to the first branch 7a and is bonded to the vertex 3a of the platform 3.

A spiral gap 10 laterally separates the platform 3 and the flexure 7 from the supporting body 2. In particular, the gap 10 runs between the supporting body 2 and the first branch 7a of the flexure 7, then along the second branch or portion 7b and along three sides of the platform 3 and finally between the platform 3 and the first branch 7a, up to the second branch 7b of the flexure 7. For example, the gap may have a width comprised between 3 μm and 30 μm, in particular 7 μm in one embodiment.

The flexure 7 is spaced from inner surfaces of the supporting body 2, the inner surfaces facing the gap 10. The first branch 7a of the flexure 7 extends from a first inner surface of the supporting body 2. The second branch 7b is spaced from a second inner surface opposite the first inner surface.

The flexure 7 has a thickness substantially equal to the thickness of the platform 3 and is shaped so as to allow, within the limits imposed by the dimensions of the gap 10, so-called in-plane movements of the platform 3, that is, in the absence of deformations of the supporting body 2, movements substantially parallel to the major face 2a of the supporting body 2 (and of the platform 3). Out-of-plane movements, that is substantially perpendicular to in-plane movements, are instead substantially prevented. Possibly, the flexure 7 may allow torsions around an axis of the first branch 7a, which may help accommodate deformations of the supporting body 2, for example following thermal stresses, without conveying significant strains to the platform 3.

The microelectromechanical pressure sensor 1 may also be provided with stoppers (not shown for simplicity) which further limit the movement of the platform 3.

The membrane 5 is formed on the platform 3 and closes a buried cavity 11, incorporated in the platform 3, on one side. In one embodiment, the buried cavity 11 is sealed by the membrane 5 and defines a pressure-controlled reference chamber. The membrane 5 is of semiconductor material, for example monocrystalline silicon, and may be capacitively coupled to one or more electrodes on the bottom of the buried cavity 11 or be provided with sensitive piezoresistive structures. On one side opposite to the buried cavity 11, the membrane 5 is exposed (directly or indirectly) to the pressure of the external environment. Conductive lines (not shown) run from the membrane 5 along the flexure 7 up to pads (not shown) and serve for the electrical coupling of the sensor 1 with the outside, for example an electronic system having the sensor 1 incorporated therein.

In one embodiment, a first dielectric or insulating layer 12, for example silicon oxide, covers the major face 2a of the supporting body 2, the flexure 7 and the platform 3 outside the membrane 5. A second dielectric or insulating layer 13, for example a thin silicon nitride layer, covers the major face 2a of the supporting body 2, the flexure 7 and the platform 3, including the membrane 5.

A sealing strip 15 extends along the gap 10 on the major face 2a of the supporting body 2 and, in part, on the flexure 7 and on the platform 3. The sealing strip 15 adheres tightly to the supporting body 2, to the flexure 7 and to the platform 3 along the edges of the gap 10 and seals the gap 10 and the recess 8 having the platform 10 housed therein.

The sealing strip 15 is of a material having a low Young's modulus and a low coefficient of thermal expansion. In general, the material forming the sealing strip 15 has a Young's modulus lower than 300 MPa and a coefficient of thermal expansion lower than 250 ppm/° C.

In one embodiment, the sealing strip 15 is of a laminated polymeric material, for example dry resist.

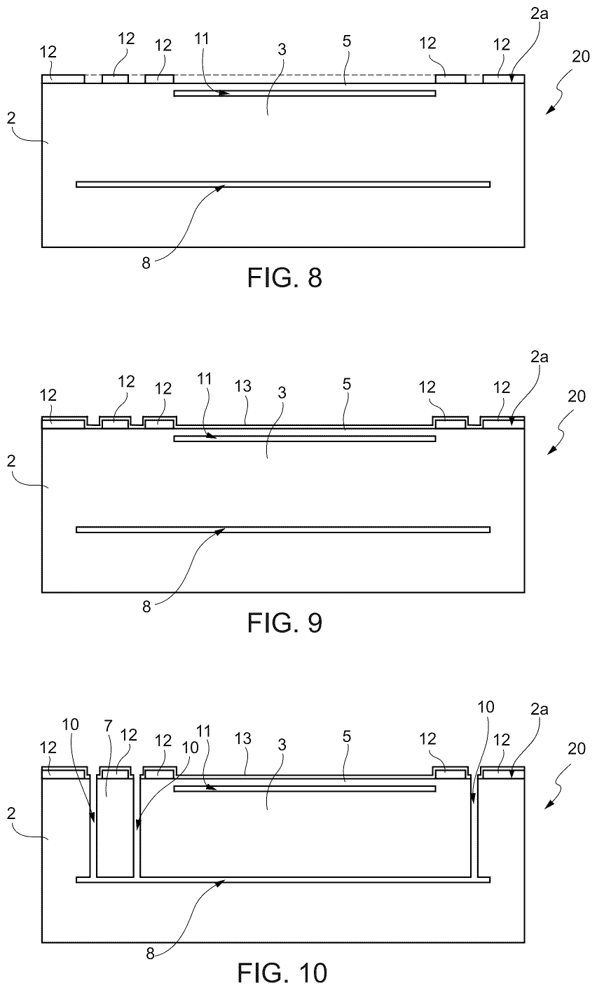

According to a different embodiment, to which FIG. 3 refers, in a microelectromechanical membrane pressure sensor 100 the sealing strip, here indicated by 115, is of an ultraviolet curable ink or UV-curable ink, deposited on the major face 2a of the supporting body 2, along the gap 10.

The sealing strip allows the sensor to be waterproofed, without appreciably affecting the thermomechanical stresses conveyed to the membrane. In practice, the presence of material across the gap maintains the decoupling of the platform from the supporting body as to the conveyance of the strains that may be generated following the deformation of the supporting body. The stresses produced by the assembling operations therefore do not give rise to significant drifts on the sensor output regardless of the base that is used. For example, with a width of the gap 10 of 7 μm, the combinations of values of the Young's modulus E and the coefficient of thermal expansion defined in Table 1 give rise to very low output drift values and in any case lower than 1 mbar.

TABLE 1

| E [MPa] | CTE [ppm/° C.] | Drift [mbar] |
|---|---|---|
| 10 | 30 | −0.00231 |
| 10 | 180 | −0.00563 |
| 100 | 100 | −0.59 |
| 150 | 100 | −0.98 |
| 200 | 30 | −0.404 |

On the one hand, therefore, waterproofed sensors may also be manufactured using less expensive bases than ceramic bases for assembling the sensor, because the deformations of the base do not affect the output owing to the fact that the membrane is formed on the movable platform. On the other hand, techniques for bonding the sensor to a support, in particular flip chip or WLCSP (Wafer Level Chip Scale Package) techniques, may also be used in a more flexible manner.

The selection of the Young's modulus and the lowest coefficient of thermal expansion in the ranges mentioned above ensures, on the one hand, that the gap remains effectively sealed and, on the other, that the sealing strip does not stiffen the structure to the point of conveying thermomechanical stresses from the supporting body to the platform and therefore the membrane. Furthermore, the sealing strip may contribute to the action of the stoppers which limit the displacements of the platform to avoid possible damage.

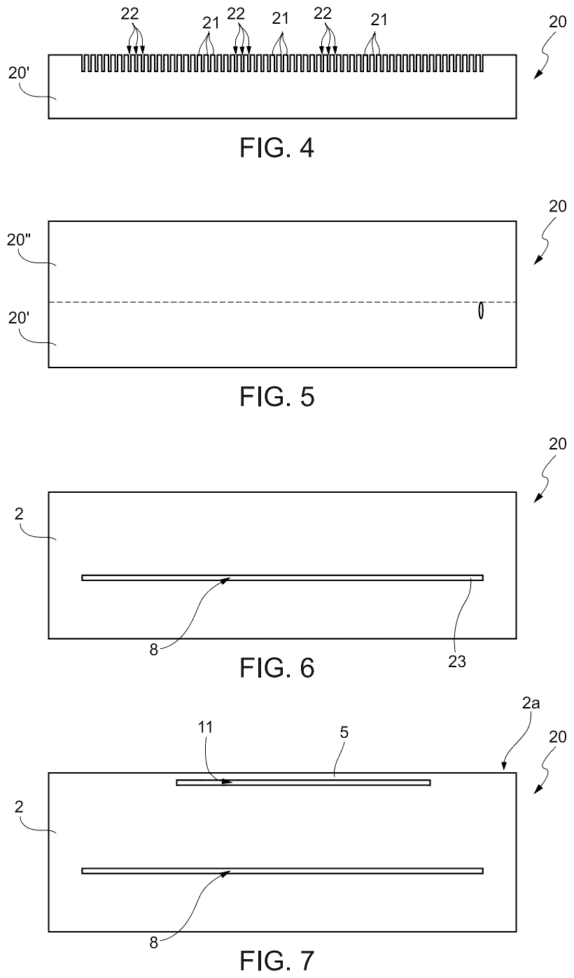

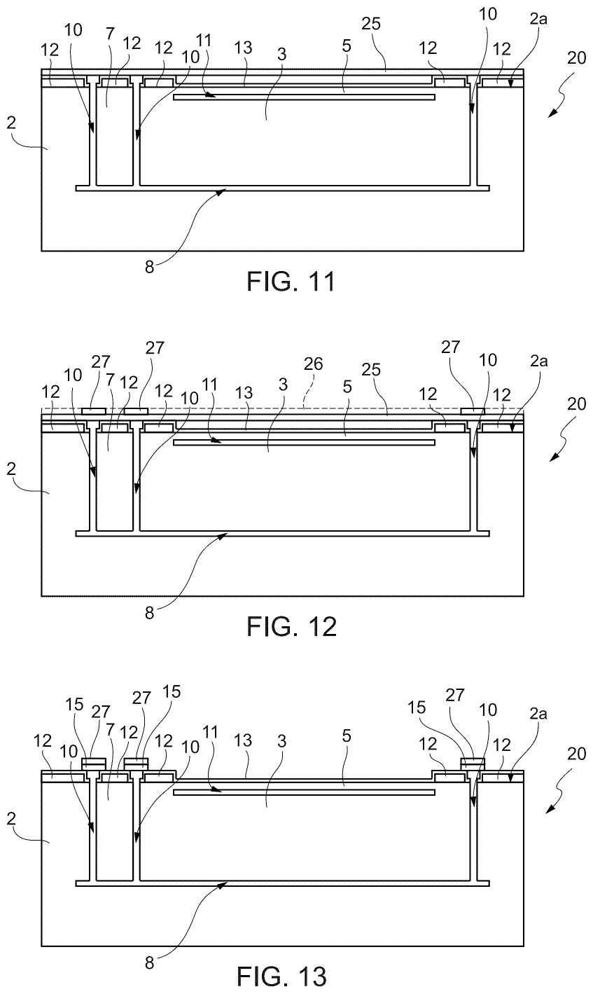

FIGS. 4-13 are a process for manufacturing the sensor 1 of FIGS. 1 and 2 starting from a semiconductor wafer 20 comprising a substrate 20′, for example of monocrystalline silicon. In an initial step (FIG. 4), the substrate 20′ is etched to form a grid or matrix of structures 21, for example pillars or walls, separated by trenches 22 in a region corresponding to a bottom of the recess 8, which will be defined below.

Subsequently (FIG. 5), an epitaxial layer 20″ of controlled thickness is grown and the trenches 22 are closed.

The material forming the structures 21 is redistributed by an annealing step and a cavity 23 is formed which substantially extends throughout the amplitude of the recess 8 (FIG. 6).

By repeating the same technique (etch, epitaxial growth and annealing, FIG. 7), the buried cavity 11 and the membrane 5 are then formed. In particular, the thickness of the membrane 5 may be determined by controlling the thickness of the new epitaxial layer, not illustrated here in detail. The substrate 20′, the epitaxial layer 20″ and the new epitaxial layer not shown define the supporting body 2 as it will be obtained at the end of the process, after dicing the wafer 20. For convenience, in FIG. 7 and following, and in the related description, reference will be made to the supporting body 2. The conductive lines for the membrane and, according to design preferences, piezoresistive regions, also not illustrated, are then formed by processing steps not illustrated.

After having formed the buried cavity 11 and the membrane 5, the first dielectric layer 12 is deposited on the wafer 20 and selectively removed on the membrane 5 and along the path where the gap 10 will subsequently be formed (FIG. 8).

The second dielectric layer 13 is conformally deposited on the wafer 20 (FIG. 9).

As shown in FIG. 10, an anisotropic etch, for example a trench etch, is then performed along the path of the gap 10, up to reaching at least the cavity 23 in depth. The trench etch opens the gap 10 and defines the platform 3, the flexure 7 and the recess 8.

However, it is understood that the structure obtained at this point may also be manufactured with alternative processes, for example using sacrificial dielectric layers to separate the platform 3 from the substrate 20 and to define the membrane 5.

A sheet 25 of polymeric material, for example dry resist, is laminated onto the wafer 20 (FIG. 11). The first dielectric layer 12 in this step also functions as a spacer and separates the sheet 25 from the membrane 5 and from the access of the gap 10.

A photoresist layer 26 is deposited on the sheet 25 and patterned by a photolithographic process, as shown in FIG. 12, to form an etching mask 27 which covers the sheet 25 along the path of the gap 10 and has a shape corresponding to the sealing strip 15.

The photoresist layer 26 is exposed and selectively removed using the etching mask 27 to form the sealing strip 15 along the edges of the gap 10 (FIG. 13).

The etching mask 27 is then removed and, after dicing the wafer 20, the structure of FIGS. 1 and 2 is obtained.

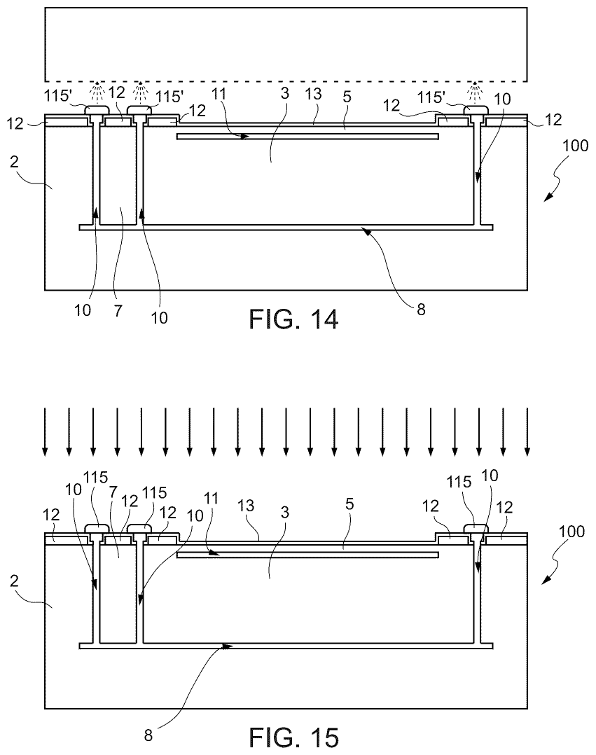

Alternatively, after opening the gap 10 and defining the platform 3, the flexure 7 and the recess 8, a strip 115′ of UV-curable ink is deposited along the gap 10 (FIG. 14). With a width of the gap 10 between 3 μm and 30 μm, as indicated above, the surface tension prevents the UV-curable ink from penetrating into the recess 8. After exposure to ultraviolet radiation which causes curing (FIG. 15), the strip 115′ partially hardens, remaining in the indicated Young's modulus range, and the structure of FIG. 3 is obtained, with the sealing strip 115.

Finally, it is clear that modifications and variations may be made to the device and method described herein without thereby departing from the scope of the present disclosure.

For example, the connection of the platform to the supporting body at a single point and through a single flexure is particularly advantageous because it minimizes the strains conveyed to the platform and to the membrane in the event of deformation of the supporting body. However, it is not the only possible solution. According to design preferences, in fact, multiple flexures may be included, for example on opposite sides of the platform. In this case, the gap may be divided into multiple sections and for each section a respective sealing strip of the type described may be provided.

Furthermore, the materials forming the sealing strip are not limited to those described.

A microelectromechanical membrane sensor comprising a supporting body (2), containing semiconductor material and having a recess (8) in a face (2a); a platform (3), housed in the recess (8) at a distance from the supporting body (2); a flexure (7), connecting the platform (3) to the supporting body (2) and configured to keep the platform (3) suspended in the recess (8), wherein a gap (10) extends between the supporting body (2), the platform (3) and the flexure (7); a membrane (5) housed in the platform (3) and delimiting a buried cavity (11) incorporated in the platform (3); and a sealing strip (15; 115) extending on the supporting body (2), on the platform (3) and on the flexure (7) along the gap (10).

The sealing strip (15; 115) is of a material having a Young's modulus lower than 300 MPa.

The sealing strip (15; 115) is of a material having a coefficient of thermal expansion lower than 250 ppm/° C.

The sealing strip (15) is a portion of a polymeric material sheet.

The sealing strip (15; 115) is of a material selected between dry resist and an UV-curable ink.

The platform (3) has a polygonal shape and wherein the flexure (7) has a first branch (7a), anchored to the supporting body (2) and extending parallel to one side of the platform (3), and a second branch (7b), consecutive to the first branch 7a and joined to the platform (3).

The gap (10) has a spiral shape and laterally separates the platform (3) and the flexure (7) from the supporting body (2).

The gap (10) runs between the supporting body (2) and the first branch (7a) of the flexure (7), around the platform (3) and between the platform (3) and the first branch (7a).

The gap (10) has a width comprised between 3 μm and 30 μm.

A process for manufacturing a microelectromechanical membrane sensor comprising in a wafer (20) containing semiconductor material, forming a recess (8) in a face (2a), a platform (3), housed in the recess (8) at a distance from the supporting body (2), and a flexure (7), connecting the platform (3) to the supporting body (2) and configured to keep the platform (3) suspended in the recess (8), wherein a gap (10) extends between the supporting body (2), the platform (3) and the flexure (7); forming a membrane (5) housed in the platform (3) and delimiting a buried cavity (11) incorporated in the platform (3); and forming a sealing strip (15; 115), extending on the supporting body (2), on the platform (3) and on the flexure (7) along the gap (10).

The sealing strip (15; 115) is of a material having a Young's modulus lower than 300 MPa.

The sealing strip (15; 115) is of a material having a coefficient of thermal expansion lower than 250 ppm/° C.

Forming the sealing strip (15) comprises laminating a sheet (25) of polymeric material on the wafer (20); forming a mask (27) covering the sheet (25) along the gap (10) and having a shape corresponding to the sealing strip (15); and selectively exposing and removing the photoresist layer (26) using the mask (27).

The sheet (25) is of dry resist.

Forming the sealing strip (115) comprises depositing a UV-curable ink strip (115′) along the gap (10); and exposing the UV-curable ink strip (115′) to ultraviolet radiation, so as to cause curing.

The various embodiments described above can be combined to provide further embodiments. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A microelectromechanical membrane sensor, comprising:
a supporting body of semiconductor material and having a recess in a face;
a platform, in the recess at a distance from the supporting body;
a flexure, connecting the platform to the supporting body and configured to keep the platform suspended in the recess, wherein a gap extends between the supporting body, the platform and the flexure;
a membrane in the platform and delimiting a buried cavity incorporated in the platform; and
a sealing strip extending on the supporting body, on the platform and on the flexure along the gap.

2. The sensor according to claim 1, wherein the sealing strip is of a material having a Young's modulus lower than 300 MPa.

3. The sensor according to claim 1, wherein the sealing strip is of a material having a coefficient of thermal expansion lower than 250 ppm/° C.

4. The sensor according to claim 1, wherein the sealing strip is a portion of a polymeric material sheet.

5. The sensor according to claim 1, wherein the sealing strip is of a material selected between dry resist and an UV-curable ink.

6. The sensor according to claim 1, wherein the platform has a polygonal shape and wherein the flexure has a first branch, anchored to the supporting body and extending coplanar to one side of the platform, and a second branch, consecutive to the first branch 7a and joined to the platform.

7. The sensor according to claim 6, wherein the gap has a spiral shape and laterally separates the platform and the flexure from the supporting body.

8. The sensor according to claim 6, wherein the gap runs between the supporting body and the first branch of the flexure, around the platform and between the platform and the first branch.

9. The sensor according to claim 1, wherein the gap has a width comprised between 3 μm and 30 μm.

10. A process for manufacturing a microelectromechanical membrane sensor, comprising:
in a wafer containing semiconductor material, forming a recess in a face, a platform, housed in the recess at a distance from a supporting body, and a flexure, connecting the platform to the supporting body and configured to keep the platform suspended in the recess, wherein a gap extends between the supporting body, the platform and the flexure;
forming a membrane housed in the platform and delimiting a buried cavity incorporated in the platform; and
forming a sealing strip, extending on the supporting body, on the platform and on the flexure along the gap.

11. The process according to claim 10, wherein the sealing strip is of a material having a Young's modulus lower than 300 MPa.

12. The process according to claim 10, wherein the sealing strip is of a material having a coefficient of thermal expansion lower than 250 ppm/° C.

13. The process according to claim 10, wherein forming the sealing strip comprises:
laminating a sheet of polymeric material on the wafer;
forming a mask covering the sheet along the gap and having a shape corresponding to the sealing strip; and
selectively exposing and removing a photoresist layer using the mask.

14. The process according to claim 13, wherein the sheet is of dry resist.

15. The process according to claim 10, wherein forming the sealing strip comprises:
depositing a UV-curable ink strip along the gap; and
exposing the UV-curable ink strip to ultraviolet radiation, so as to cause curing.

16. A device, comprising:
a substrate having a recess in a first surface, the recess having a second surface opposite the first surface;
a gap delimiting inner surfaces of the substrate, the gap extending from the first surface of the substrate to the second surface of the recess;
a suspended platform over the second surface of the recess;
an extension coupling the suspended platform to the substrate, the extension extending from a first inner surface of the substrate, the first inner surface transverse the first surface of the substrate;
a buried cavity in the suspended platform and over the second surface of the recess; and
a sealing strip on the gap.

17. The device of claim 16, wherein the extension includes a first portion transverse a second portion extending through the gap, the first portion extending to the second portion along a first direction, and the second portion extending in a second direction transverse the first direction.

18. The device of claim 17, wherein the first portion of the extension extends from the first inner surface of the substrate and the second portion is spaced from a second inner surface of the substrate, the second inner surface opposite the first inner surface.

19. The device of claim 18, wherein the extension has a first dimension greater than a second dimension, the first portion extending along the first direction for the first dimension, and the second portion extending along the second direction for the second dimension.

20. The device of claim 16, further comprising an insulating layer on the first surface of the substrate and the suspended platform, the sealing strip is on portions of the insulating layer.
